(19) United States
(12) Patent Application Publication
(10) Pub. No.: US 2025/0187110 A1
(43) Pub. Date: Jun. 12, 2025

(54) LASER PROCESSING SYSTEM, LASER PROCESSING METHOD, AND ELECTRONIC DEVICE MANUFACTURING METHOD

(71) Applicant: Gigaphoton Inc., Tochigi (JP)

(72) Inventor: Yuki TAMARU, Oyama-shi (JP)

(73) Assignee: Gigaphoton Inc., Tochigi (JP)

(21) Appl. No.: 18/936,476

(22) Filed: Nov. 4, 2024

(30) Foreign Application Priority Data
Dec. 12, 2023 (JP) 2023-209538

(51) Int. Cl. B23K 26/066; B23K 26/06; B23K 26/382; B23K 101/36

(52) U.S. Cl. CPC B23K 26/066; B23K 26/0626; B23K 26/0643; B23K 26/0665; B23K 26/382; B23K 2101/36

(57) ABSTRACT

A laser processing system includes a laser apparatus that outputs a deep ultraviolet laser beam in response to a light emission trigger signal, an optical isolator including a polarizer, a deep ultraviolet light transmitting element, and a piezoelectric element connected to the deep ultraviolet light transmitting element, and a processor that supplies, to the piezoelectric element, a drive signal having a voltage changeable with a natural frequency of the deep ultraviolet light transmitting element, and transmits the light emission trigger signal to the laser apparatus using the natural frequency or a frequency obtained by dividing the natural frequency as a repetition frequency so that the deep ultraviolet light transmitting element functions as a ¼ wave plate by stress birefringence due to force from the piezoelectric element, and processing is performed by irradiating a workpiece with the laser beam from the optical isolator.

### CROSS-REFERENCE TO RELATED APPLICATIONS

The present application claims the benefit of Japanese Patent Application No. 2023-209538, filed on Dec. 12, 2023, the entire contents of which are hereby incorporated by reference.

### BACKGROUND

### 1. Technical Field

The present disclosure relates to a laser processing system, a laser processing method, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser apparatus for exposure, a KrF excimer laser apparatus that outputs a laser beam having a wavelength of about 248.0 nm and an ArF excimer laser apparatus that outputs a laser beam having a wavelength of about 193.4 nm are used.

Since the excimer laser beams have a pulse width of about several 10 ns and short wavelengths of 248.0 nm and 193.4 nm, the excimer laser beams are sometimes used for direct processing of a polymer material, a glass material, or the like.

A chemical bond in a polymer material can be cut by an excimer laser beam having photon energy higher than bond energy. Therefore, it is known that non-heating processing of a polymer material is made possible by an excimer laser beam, and a processing shape becomes fine.

In addition, since glass and ceramics or the like have a high absorptance to an excimer laser beam, it is known that even a material that is difficult to be processed by visible and infrared laser beams can be processed by an excimer laser beam.

Spectral linewidths of spontaneous oscillation beams of the KrF excimer laser apparatus and the ArF excimer laser apparatus are as wide as from 350 μm to 400 μm. Therefore, when a projection lens is formed of a material that transmits ultraviolet light such as KrF and ArF laser beams, chromatic aberration may occur. As a result, the resolution may decrease. Thus, the spectral linewidth of the laser beam output from the gas laser apparatus needs to be narrowed to an extent that the chromatic aberration is ignorable. Therefore, in a laser resonator of the gas laser apparatus, a line narrowing module (LNM) including a line narrowing element (such as etalon or grating) may be provided in order to narrow the spectral linewidth. Hereinafter, a gas laser apparatus with a narrowed spectral linewidth is referred to as a line narrowing gas laser apparatus.

### LIST OF DOCUMENTS

### Patent Documents

Patent Document 1: U.S. Pat. No. 9,802,270
Patent Document 2: Japanese Unexamined Patent Application Publication No. 2020-60449

### SUMMARY

A laser processing system according to one aspect of the present disclosure includes a laser apparatus, an optical isolator, and a processor. The laser apparatus is configured to output a deep ultraviolet laser beam in response to reception of a light emission trigger signal. The optical isolator includes a polarizer and a deep ultraviolet light transmitting element disposed on an optical path of the laser beam, and a piezoelectric element connected to the deep ultraviolet light transmitting element. The processor is configured to supply, to the piezoelectric element, a drive signal having a voltage changeable with a natural frequency of the deep ultraviolet light transmitting element, and to transmit the light emission trigger signal to the laser apparatus using the natural frequency or a frequency obtained by dividing the natural frequency as a repetition frequency so that the deep ultraviolet light transmitting element functions as a ¼ wave plate by stress birefringence generated in response to force applied from the piezoelectric element at a timing when the laser beam passes through the deep ultraviolet light transmitting element. Processing is performed by irradiating a workpiece with the laser beam from the optical isolator.

A laser processing method according to one aspect of the present disclosure is for performing processing through irradiation to a workpiece by a laser processing system including a laser apparatus configured to output a deep ultraviolet laser beam in response to reception of a light emission trigger signal and an optical isolator including a polarizer and a deep ultraviolet light transmitting element disposed on an optical path of the laser beam, and a piezoelectric element connected to the deep ultraviolet light transmitting element. The method includes supplying, to the piezoelectric element, a drive signal having a voltage changeable with a natural frequency of the deep ultraviolet light transmitting element, transmitting the light emission trigger signal to the laser apparatus using the natural frequency or a frequency obtained by dividing the natural frequency as a repetition frequency so that the deep ultraviolet light transmitting element functions as a ¼ wave plate by stress birefringence generated in response to force applied from the piezoelectric element at a timing when the laser beam passes through the deep ultraviolet light transmitting element, and performing processing by irradiating the workpiece with the laser beam output from the optical isolator.

An electronic device manufacturing method according to one aspect of the present disclosure includes forming, by a laser processing system, a plurality of through-holes in a glass substrate as a workpiece, coupling and electrically connecting an interposer and an integrated circuit chip to each other, the interposer including the glass substrate and conductors provided in the respective through-holes, and coupling and electrically connecting the interposer and a circuit board to each other. The laser processing system includes a laser apparatus configured to output a deep ultraviolet laser beam in response to reception of a light emission trigger signal, an optical isolator including a polarizer and a deep ultraviolet light transmitting element disposed on an optical path of the laser beam, and a piezoelectric element connected to the deep ultraviolet light transmitting element, and a processor configured to supply, to the piezoelectric element, a drive signal having a voltage changeable with a natural frequency of the deep ultraviolet light transmitting element, and to transmit the light emission trigger signal to the laser apparatus using the natural frequency or a frequency obtained by dividing the natural frequency as a repetition frequency so that the deep ultraviolet light transmitting element functions as a ¼ wave plate by stress birefringence generated in response to force applied from the piezoelectric element at a timing when the laser beam passes through the deep ultraviolet light transmitting element. Processing is performed by irradiating the workpiece with the laser beam output from the optical isolator.

### BRIEF DESCRIPTION OF THE DRAWINGS

Some embodiments of the present disclosure will be described below, by way of example only, with reference to the accompanying drawings.

FIG. 1 is a diagram schematically illustrating a configuration of a laser processing system according to a comparative example.

FIG. 2 is a diagram schematically illustrating a configuration of a laser apparatus.

FIG. 3 is a diagram illustrating a state where a laser beam enters an optical isolator from an upstream side.

FIG. 4 is a diagram illustrating a state where a laser beam enters an optical isolator from a downstream side.

FIG. 5 is a diagram schematically illustrating a configuration of a laser processing system according to a first embodiment.

FIG. 6 is a diagram illustrating timings of various kinds of signals regarding synchronization control between a laser apparatus and a PEM.

FIG. 7 is a diagram illustrating a state where a laser beam enters an optical isolator from an upstream side.

FIG. 8 is a diagram illustrating a state where a laser beam enters an optical isolator from a downstream side.

FIG. 9 is a diagram schematically illustrating a configuration of a laser processing system according to a second embodiment.

FIG. 10 is a diagram schematically illustrating a configuration of a laser apparatus according to a modification.

FIG. 11 is a diagram schematically illustrating a configuration of an electronic device.

FIG. 12 is a diagram illustrating an electronic device manufacturing method.

### DESCRIPTION OF EMBODIMENTS

### <Contents>

1. Terms
   1.1 Polarizer
   1.2 ¼ Wave Plate
2. Comparative Example
   2.1 Configuration
   2.2 Operation
2.3 Problem
3. First Embodiment
   3.1 Configuration
   3.2 Operation
   3.3 Effect
4. Second Embodiment
   4.1 Configuration
   4.2 Operation
4.3 Effect
5. Modification of Laser Apparatus
6. Electronic Device Manufacturing Method
7. Configuration Example of Laser Processing Processor

Hereinafter, embodiments of the present disclosure will be described in detail with reference to the drawings. The embodiments described below show some examples of the present disclosure and do not limit contents of the present disclosure. In addition, all configurations and operations described in the embodiments are not necessarily essential as configurations and operations of the present disclosure. The same components are denoted by the same reference signs, and any redundant description thereof is omitted.

### 1. Terms

### 1.1 Polarizer

In the present disclosure, a polarizer is an optical element that separates incident light into two linearly polarized light beams having orthogonal polarization directions. Specifically, the polarizer according to the present disclosure is an optical element that transmits one of two linearly polarized light beams having orthogonal polarization directions and reflects the other.

### 1.2 ¼ Wave Plate

In the present disclosure, a ¼ wave plate is an optical element that gives a phase difference (90°+n×180°) to two orthogonal polarized components. Here, n is an integer equal to or larger than 0. Note that the phase difference for the optical element to actually function as a ¼ wave plate may deviate from the aforementioned phase difference (90°+n×180°) by about several degrees.

### 2. Comparative Example

### 2.1 Configuration

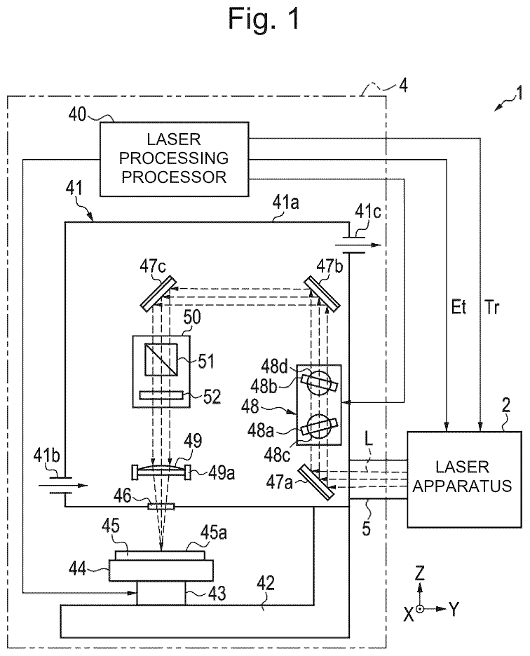

FIG. 1 schematically illustrates a configuration of a laser processing system 1 according to a comparative example. The comparative example is an example recognized by the applicant as known only by the applicant, and is not a publicly known example admitted by the applicant.

The laser processing system 1 mainly includes a laser apparatus 2 and a laser processing apparatus 4. The laser processing system 1 is used for laser hole processing of forming holes such as via holes in a glass substrate for an interposer.

The laser apparatus 2 outputs a deep ultraviolet pulse laser beam. For example, the laser apparatus 2 is an ArF excimer laser apparatus using an ArF laser gas containing argon (Ar) and fluorine (F) as a laser gas. The laser apparatus 2 outputs a linearly polarized deep ultraviolet pulse laser beam having a center wavelength of about 193.4 nm. Hereinafter, the deep ultraviolet pulse laser beam output from the laser apparatus 2 is simply referred to as a laser beam L. The deep ultraviolet pulse laser beam is an example of “deep ultraviolet laser beam” according to technology of the present disclosure. Further, deep ultraviolet refers to, for example, a wavelength range of 100 nm to 280 nm.

The laser apparatus 2 and the laser processing apparatus 4 are connected by an optical path pipe 5. The optical path pipe 5 is disposed on an optical path of the laser beam L between an exit port of the laser apparatus 2 and an entrance port of the laser processing apparatus 4.

The laser processing apparatus 4 includes a laser processing processor 40, an optical device 41, a frame 42, a moving stage 43, and a table 44. The optical device 41 and the moving stage 43 are mounted on the frame 42.

The table 44 supports a workpiece 45. The workpiece 45 is a processing target that is irradiated with the laser beam L and is subjected to laser hole processing. For example, the workpiece 45 is a quartz glass substrate.

The moving stage 43 supports the table 44. The workpiece 45 is fixed on the table 44. The moving stage 43 is movable in an X direction, a Y direction, and a Z direction, and a position of the workpiece 45 can be adjusted by adjusting a position of the table 44. The X direction, the Y direction, and the Z direction are orthogonal to each other. The X direction and the Y direction are parallel to a surface 45a of the workpiece 45 on which the laser beam L is incident. The Z direction is orthogonal to the surface 45a.

Under control of the laser processing processor 40, the moving stage 43 adjusts the position of the workpiece 45 so that a desired processing position on the surface 45a is irradiated with the laser beam L output from the optical device 41.

The optical device 41 includes a housing 41a, a window 46, high reflective mirrors 47a, 47b, and 47c, an attenuator 48, a light condensing optical system 49, and an optical isolator 50. The high reflective mirrors 47a, 47b, and 47c, the attenuator 48, the light condensing optical system 49, and the optical isolator 50 are provided inside the housing 41a. The window 46 is disposed in a hole formed in the housing 41a via an unillustrated O-ring or the like, on an optical path between the light condensing optical system 49 and the moving stage 43.

The housing 41a is provided with a suction port 41b for sucking a nitrogen gas into the housing 37 and a discharge port 41c for discharging the nitrogen gas from the housing 41a to the outside. An unillustrated nitrogen gas supply source is connected to the suction port 41b. An unillustrated discharge device is connected to the discharge port 41c. The suction port 41b and the discharge port 41c are sealed by unillustrated O-rings so as to suppress outside air from entering the housing 41a.

Each of the high reflective mirrors 47a, 47b, and 47c is fixed to an unillustrated holder. The high reflective mirror 47a is disposed so as to reflect the laser beam L that has passed through the optical path pipe 5, and to make the reflected laser beam L pass through the attenuator 48 to be incident on the high reflective mirror 47b.

The attenuator 48 is disposed in the housing 41a on an optical path between the high reflective mirror 47a and the high reflective mirror 47b. The attenuator 48 includes, for example, two partial reflective mirrors 48a and 48b and rotating stages 48c and 48d of the partial reflective mirrors. The partial reflective mirrors 48a and 48b are optical elements transmittances of which change depending on an incident angle of the laser beam L. The incident angles of the laser beam L on the partial reflective mirrors 48a and 48b are adjusted by the respective rotating stages 48c and 48d.

The high reflective mirror 47b is disposed so as to reflect the laser beam L that has passed through the attenuator 48 and to make the reflected laser beam L incident on the high reflective mirror 47c.

The optical isolator 50 includes a polarizer 51 and a ¼ wave plate 52, and is disposed on an optical path of the laser beam L reflected by the high reflective mirror 47c. For example, the polarizer 51 is a polarizing beam splitter that transmits p-polarized light and reflects s-polarized light, and is disposed such that the laser beam L enters the polarizer 51 as the p-polarized light.

The ¼ wave plate 52 is disposed on an optical path of the laser beam L transmitted through the polarizer 51 so as to convert the incoming laser beam L from linearly polarized light to circularly polarized light and to output the circularly polarized light. Specifically, the ¼ wave plate 52 is disposed such that an azimuth angle of a polarization direction of the laser beam L with respect to a fast axis or a slow axis thereof is 45°.

The light condensing optical system 49 is fixed to a holder 49a, and is disposed so as to condense the laser beam L output from the optical isolator 50 onto the workpiece 45 via the window 46.

The laser processing processor 40 transmits target pulse energy Et and a light emission trigger signal Tr to the laser apparatus 2. The target pulse energy Et has a target value of pulse energy of the laser beam L. The light emission trigger signal Tr is a trigger signal for causing the laser apparatus 2 to output the laser beam L for one pulse, and is generated based on a master signal having a predetermined frequency. The laser processing processor 40 is an example of “processor” according to the technology of the present disclosure.

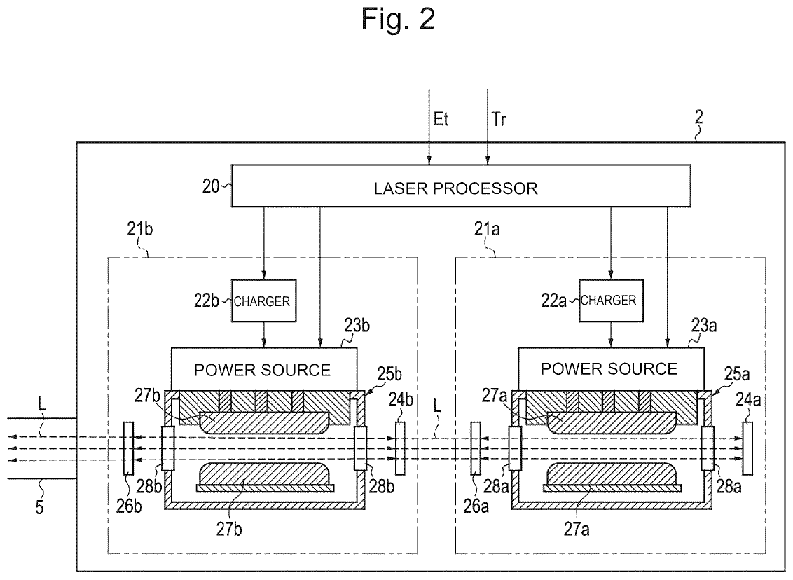

FIG. 2 schematically illustrates a configuration of the laser apparatus 2. The laser apparatus 2 includes a laser processor 20, a master oscillator 21a, and an excimer amplifier 21b. In the present comparative example, the excimer amplifier 21b is a power oscillator as an oscillator amplifier.

The master oscillator 21a is an excimer laser apparatus including a charger 22a, a power source 23a, a rear mirror 24a, a chamber 25a, and an output coupling mirror 26a. In the chamber 25a, a pair of discharge electrodes 27a are provided, and the laser gas is enclosed. Further, the chamber 25a is provided with a pair of windows 28a on positions where the laser beam L passes through. The pair of windows 28a are disposed such that the incident angle of the laser beam L is a Brewster's angle. The rear mirror 24a and the output coupling mirror 26a constitute an optical resonator.

The power source 23a is a pulse power module to which the charger 22a is connected. The rear mirror 24a is a total reflection mirror. The output coupling mirror 26a is a partial reflective mirror in which a reflectance of the laser beam L is in a range of 40% to 60%.

The excimer amplifier 21b includes a charger 22b, a power source 23b, a rear mirror 24b, a chamber 25b, and an output coupling mirror 26b. In the chamber 25b, a pair of discharge electrodes 27b are provided, and the laser gas is enclosed. Further, the chamber 25b is provided with a pair of windows 28b on positions where the laser beam L passes through. The pair of windows 28b are disposed such that the incident angle of the laser beam L is the Brewster's angle. The rear mirror 24b and the output coupling mirror 26b constitute an optical resonator.

The power source 23b is a pulse power module to which the charger 22b is connected. The rear mirror 24b is a partial reflective mirror in which the reflectance of the laser beam L is in a range of 50% to 90%.

The laser processor 20 controls the charger 22a and the power source 23a of the master oscillator 21a, and the charger 22b and the power source 23b of the excimer amplifier 21b. Specifically, the laser processor 20 sets a charging voltage to each of the chargers 22a and 22b, and controls ON/OFF of switches included in the power sources 23a and 23b.

### 2.2 Operation

Next, an operation of the laser processing system 1 according to the comparative example will be described. First, the laser processing processor 40 adjusts the position of the workpiece 45 by controlling the moving stage 43 so that a beam waist position of the laser beam L condensed by the light condensing optical system 49 is at a predetermined depth from the surface 45a inside the workpiece 45.

Next, the laser processing processor 40 transmits the target pulse energy Et to the laser apparatus 2 and controls a transmittance of the attenuator 48 so that fluence of the laser beam L with which the surface 45a of the workpiece 45 is irradiated becomes a target value.

Next, the laser processing processor 40 transmits the light emission trigger signal Tr of a predetermined pulse count at a predetermined repetition frequency f_{L} to the laser apparatus 2.

Upon receiving the light emission trigger signal Tr, the laser processor 20 sets the charging voltage corresponding to the target pulse energy Et to the chargers 22a and 22b. Further, the laser processor 20 controls the respective switches of the power sources 23a and 23b so that the excimer amplifier 21b discharges to amplify the laser beam L at a timing when the laser beam L generated by discharge in the master oscillator 21a passes through the excimer amplifier 21b.

Consequently, the laser beam L is output from the laser apparatus 2 in synchronization with the light emission trigger signal Tr and enters the optical device 41 of the laser processing apparatus 4. The laser beam L that has entered the optical device 41 is reflected by the high reflective mirror 47a and enters the attenuator 48. The laser beam L that has entered the attenuator 48 is transmitted through the partial reflective mirrors 48a and 48b and is made incident on the high reflective mirror 47b.

The laser beam L reflected by the high reflective mirror 47b is reflected by the high reflective mirror 47c and enters the optical isolator 50. The laser beam L that has entered the optical isolator 50 is transmitted through the polarizer 51 and the ¼ wave plate 52, and enters the light condensing optical system 49. The laser beam L that has entered the light condensing optical system 49 is condensed at the predetermined depth from the surface 45a inside the workpiece 45 via the window 46.

By repeatedly irradiating the workpiece 45 with the laser beam L, hole processing is performed on the workpiece 45. Note that a matter of concern is that a part of the laser beam L incident on the workpiece 45 returns as return light Lr to the optical device 41 via the window 46 by being reflected by the surface 45a, thereby damaging the optical elements in the optical device 41. The optical isolator 50 has a function of suppressing the return light Lr from returning to an upstream side in the optical device 41.

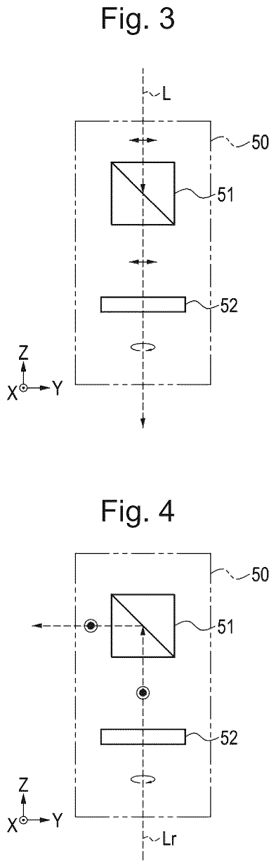

FIG. 3 and FIG. 4 illustrate an effect of the optical isolator 50 according to the comparative example. FIG. 3 illustrates a state where the laser beam L enters the optical isolator 50 from the upstream side. FIG. 4 illustrates a state where the return light Lr enters the optical isolator 50 from a downstream side.

As illustrated in FIG. 3, the linearly polarized laser beam L enters the optical isolator 50 from the upstream side. The laser beam L that has entered the optical isolator 50 enters the polarizer 51 as p-polarized light to be transmitted through the polarizer 51, and enters the ¼ wave plate 52. The p-polarized laser beam L that has entered the ¼ wave plate 52 is converted to circularly polarized light by the ¼ wave plate 52 and is output from the optical isolator 50.

As illustrated in FIG. 4, the circularly polarized return light Lr enters the optical isolator 50 from the downstream side. The return light Lr that has entered the optical isolator 50 enters the ¼ wave plate 52 and is converted to linearly polarized light. The polarization direction of the return light Lr converted to the linearly polarized light is orthogonal to the polarization direction of the laser beam L entering the ¼ wave plate 52 from the upstream side. Therefore, the return light Lr enters the polarizer 51 as the s-polarized light and is reflected by the polarizer 51. This suppresses the return light Lr from returning to the upstream side of the optical isolator 50.

### 2.3 Problem

Next, a problem of the laser processing system 1 according to the comparative example will be described. The optical isolator 50 used in the laser processing system 1 according to the comparative example includes, as described above, the ¼ wave plate 52 for converting the linearly polarized light to the circularly polarized light and converting the circularly polarized light to the linearly polarized light. The ¼ wave plate 52 is formed of magnesium fluoride, sapphire, quartz, or the like, and has a problem of low durability against deep ultraviolet light used as the laser beam L. Therefore, it is a problem to realize an optical isolator having high durability against deep ultraviolet light.

### 3. First Embodiment

A laser processing system 1a according to a first embodiment of the present disclosure will be described. Any component same as that described above is denoted by the same reference sign, and redundant description thereof is omitted unless specific description is needed.

### 3.1 Configuration

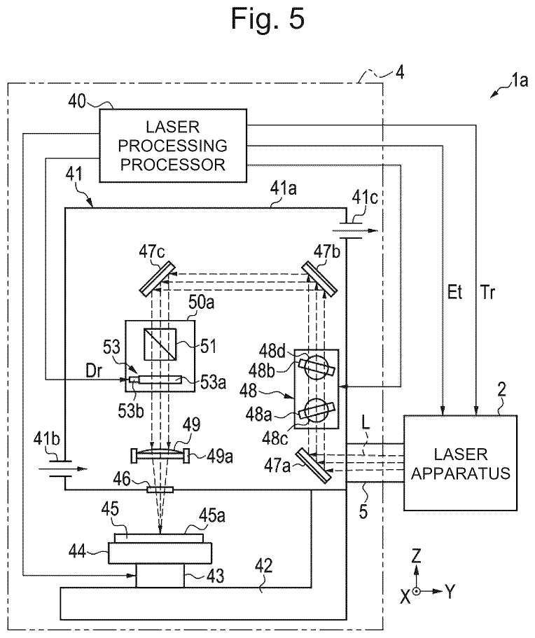

FIG. 5 schematically illustrates a configuration of the laser processing system 1a according to the first embodiment. The laser processing system 1a differs from the configuration of the laser processing system 1 according to the comparative example only in using an optical isolator 50a instead of the optical isolator 50 according to the comparative example.

The optical isolator 50a includes the polarizer 51 and a photoelastic modulator (PEM) 53, and is disposed on an optical path of the laser beam L reflected by the high reflective mirror 47c. The polarizer 51 has the same configuration as that of the comparative example, and is disposed such that the laser beam L enters the polarizer 51 as the p-polarized light.

The PEM 53 includes a deep ultraviolet light transmitting element 53a and a piezoelectric element 53b. The deep ultraviolet light transmitting element 53a is an optical element that is transmissive to deep ultraviolet light having a wavelength of about 193.4 nm or the like, and is made of, for example, calcium fluoride or synthetic quartz in a plate shape. The deep ultraviolet light transmitting element 53a is disposed on an optical path of the laser beam L transmitted through the polarizer 51.

The deep ultraviolet light transmitting element 53a has a natural frequency f_{C} that is determined by its material, shape, and size. In addition, the deep ultraviolet light transmitting element 53a generates stress birefringence in response to force applied from the outside. Specifically, the deep ultraviolet light transmitting element 53a generates stress by the force applied from the outside, and generates the stress birefringence corresponding to the stress. In other words, the deep ultraviolet light transmitting element 53a functions as a wave plate that gives a phase difference corresponding to the stress to two orthogonal polarized components of the laser beam L.

The piezoelectric element 53b is attached to the deep ultraviolet light transmitting element 53a, and applies periodically changing force to the deep ultraviolet light transmitting element 53a based on a drive signal Dr supplied from the laser processing processor 40. A signal line through which the laser processing processor 40 supplies the drive signal Dr to the piezoelectric element 53b is connected between the laser processing processor 40 and the piezoelectric element 53b.

### 3.2 Operation

Next, an operation of the laser processing system 1a according to the first embodiment will be described. The operation of the laser processing system 1a is the same as that of the comparative example except synchronization control between the laser apparatus 2 and the PEM 53.

The laser processing processor 40 generates the drive signal Dr having a voltage changeable with the natural frequency f_{C} of the deep ultraviolet light transmitting element 53a, and supplies the drive signal Dr to the piezoelectric element 53b.

Further, the laser processing processor 40 generates the light emission trigger signal Tr having the natural frequency f_{C} or a frequency obtained by dividing the natural frequency f_{C} as the repetition frequency f_{L}, and transmits the light emission trigger signal Tr to the laser apparatus 2. That is, the natural frequency f_{C} and the repetition frequency f_{L} satisfy relation of f_{L}=f_{C}/k. Here, k is an integer equal to or larger than 1.

The laser beam L output from the laser apparatus 2 in response to the light emission trigger signal Tr enters the optical device 41, and then enters the optical isolator 50a via the high reflective mirror 47a, the attenuator 48, the high reflective mirror 47b, and the high reflective mirror 47c.

The laser beam L that has entered the optical isolator 50a is transmitted through the polarizer 51 and enters the deep ultraviolet light transmitting element 53a. The deep ultraviolet light transmitting element 53a gives the phase difference corresponding to the stress generated by the force applied from the piezoelectric element 53b to the laser beam L that has entered, and outputs the laser beam L.

The laser processing processor 40 performs the synchronization control between the laser apparatus 2 and the PEM 53 so that the deep ultraviolet light transmitting element 53a functions as a ¼ wave plate at a timing when the laser beam L passes through the deep ultraviolet light transmitting element 53a. Thus, the optical isolator 50a has the same effect as the optical isolator 50 according to the comparative example.

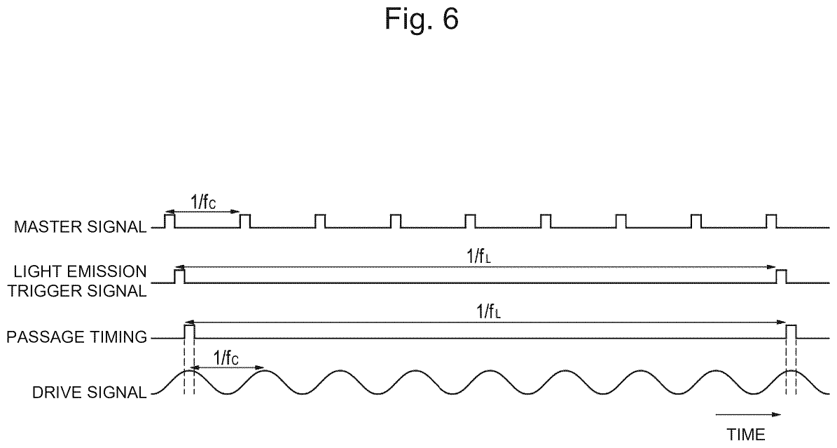

FIG. 6 illustrates timings of various kinds of signals regarding the synchronization control between the laser apparatus 2 and the PEM 53. The laser processing processor 40 sets a frequency of the master signal as the natural frequency f_{C}, and generates the drive signal Dr based on the master signal. For example, the drive signal Dr is a sinusoidal signal the voltage of which changes in a cycle of 1/f_{C}. For example, for the deep ultraviolet light transmitting element 53a, the stress changes in the cycle of 1/f_{C}, and the deep ultraviolet light transmitting element 53a functions as a ¼ wave plate at a timing when the stress becomes maximum. For example, the natural frequency f_{C} is 48 kHz.

The laser processing processor 40 generates the light emission trigger signal Tr based on the master signal. For example, the laser processing processor 40 generates the light emission trigger signal Tr having the repetition frequency f_{L} of 6 kHz with k=8.

Note that, after the laser processing processor 40 transmits the light emission trigger signal Tr to the laser apparatus 2 as illustrated as a passage timing in FIG. 6, a fixed delay time is generated before the timing when the laser beam L passes through the deep ultraviolet light transmitting element 53a. Therefore, the laser processing processor 40 transmits the light emission trigger signal Tr at a timing expecting the delay time for the timing when the drive signal Dr becomes maximum, that is, the timing when the deep ultraviolet light transmitting element 53a functions as a ¼ wave plate.

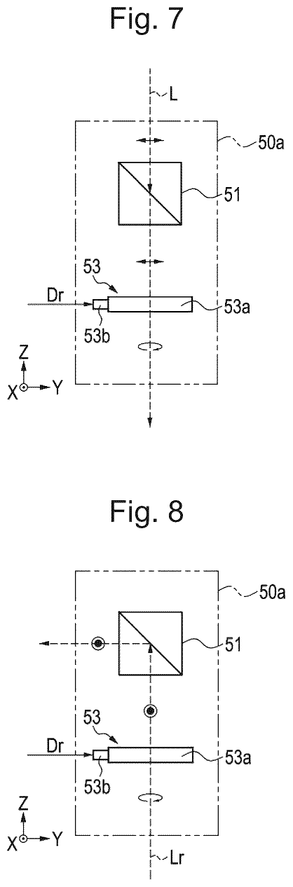

FIG. 7 and FIG. 8 illustrate the effect of the optical isolator 50a according to the first embodiment. FIG. 7 illustrates a state where the laser beam L enters the optical isolator 50a from the upstream side. FIG. 8 illustrates a state where the return light Lr enters the optical isolator 50a from the downstream side.

As illustrated in FIG. 7, the linearly polarized laser beam L enters the optical isolator 50a from the upstream side. The laser beam L that has entered the optical isolator 50a enters the polarizer 51 as the p-polarized light to be transmitted through the polarizer 51, and enters the deep ultraviolet light transmitting element 53a. The laser beam L is then converted to the circularly polarized light since the deep ultraviolet light transmitting element 53a functions as a ¼ wave plate, and is output from the optical isolator 50a.

As illustrated in FIG. 8, the circularly polarized return light Lr enters the optical isolator 50a from the downstream side. The return light Lr that has entered the optical isolator 50a enters the deep ultraviolet light transmitting element 53a. The return light Lr is then converted to the linearly polarized light since the deep ultraviolet light transmitting element 53a functions as a ¼ wave plate. The return light Lr output from the deep ultraviolet light transmitting element 53a enters the polarizer 51 as the s-polarized light and is reflected by the polarizer 51. This suppresses the return light Lr from returning to the upstream side of the optical isolator 50a.

### 3.3 Effect

According to the present embodiment, since the optical isolator 50a is constructed with use of the PEM 53 including the deep ultraviolet light transmitting element 53a, it is possible to realize the optical isolator 50a having higher durability against deep ultraviolet light than the optical isolator 50 according to the comparative example.

### 4. Second Embodiment

A laser processing system 1b according to a second embodiment of the present disclosure will be described. Any component same as that described above is denoted by the same reference sign, and redundant description thereof is omitted unless specific description is needed.

The laser processing system 1a according to the first embodiment performs the hole processing by condensing the laser beam L on the workpiece 45. On the other hand, the laser processing system 1b according to the second embodiment performs the hole processing by projecting an image of the laser beam L formed by a photomask 61 onto the workpiece 45.

### 4.1 Configuration

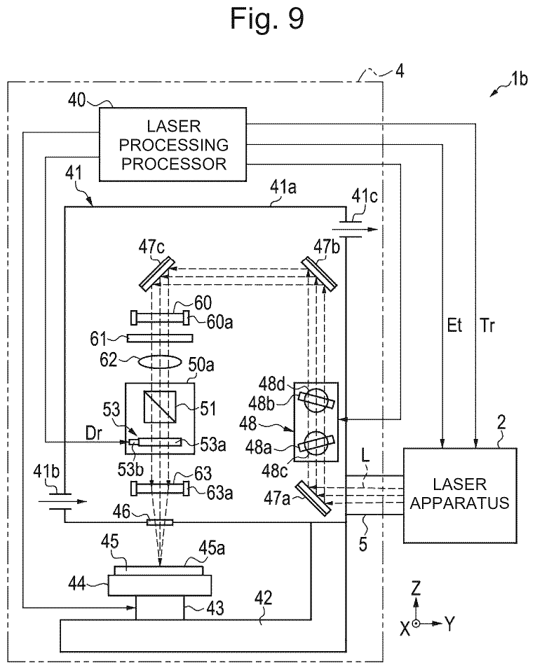

FIG. 9 schematically illustrates a configuration of the laser processing system 1b according to the second embodiment. The laser processing system 1b according to the present embodiment differs from the first embodiment only in the configuration in the optical device 41.

In the present embodiment, an illumination optical system 60, the photomask 61, and a collimating lens 62 are provided on an optical path of the laser beam L between the high reflective mirror 47c and the optical isolator 50a. Further, in the present embodiment, a projection optical system 63 is provided on an optical path of the laser beam L between the optical isolator 50a and the window 46 instead of the light condensing optical system 49. The illumination optical system 60 is held by a holder 60a. The projecting optical system 63 is held by a holder 63a.

The illumination optical system 60, the photomask 61, and the collimating lens 62 are disposed in this order from the high reflective mirror 47c. An unillustrated hole is formed in the photomask 61. Alternatively, a transmission region and a shielding region for the deep ultraviolet light are formed in the photomask 61. The optical isolator 50a may be disposed on the downstream side of the photomask 61, that is, on the side of the workpiece 45, and on the upstream side of the projection optical system 63.

### 4.2 Operation

Next, an operation of the laser processing system 1b according to the second embodiment will be described. The operation of the laser processing system 1b is the same as that of the first embodiment except that an optical effect in the optical device 41 is different.

In the present embodiment, the laser beam L reflected by the high reflective mirror 47c enters the illumination optical system 60. The illumination optical system 60 illuminates the photomask 61 with the laser beam L that has entered. The laser beam L that has passed through the hole or the transmission region formed in the photomask 61 enters the optical isolator 50a via the collimating lens 62. The laser beam L that has entered the optical isolator 50a is transmitted through the polarizer 51 and the deep ultraviolet light transmitting element 53a and enters the projection optical system 63. The laser beam L that has entered the projection optical system 63 is projected onto the workpiece 45 as an image representing a shape of the hole or the transmission region formed in the photomask 61. The effect of the optical isolator 50a is the same as that of the first embodiment.

### 4.3 Effect

According to the present embodiment, since the optical isolator 50a is disposed on the downstream side of the photomask 61, the return light Lr can be suppressed from entering the photomask 61, and breakage of the photomask 61 can be suppressed. This increases lifetime of the laser processing system 1b.

### 5. Modification of Laser Apparatus

Next, various kinds of modifications of the laser apparatus 2 will be described. The following modifications can be applied to both the first embodiment and the second embodiment.

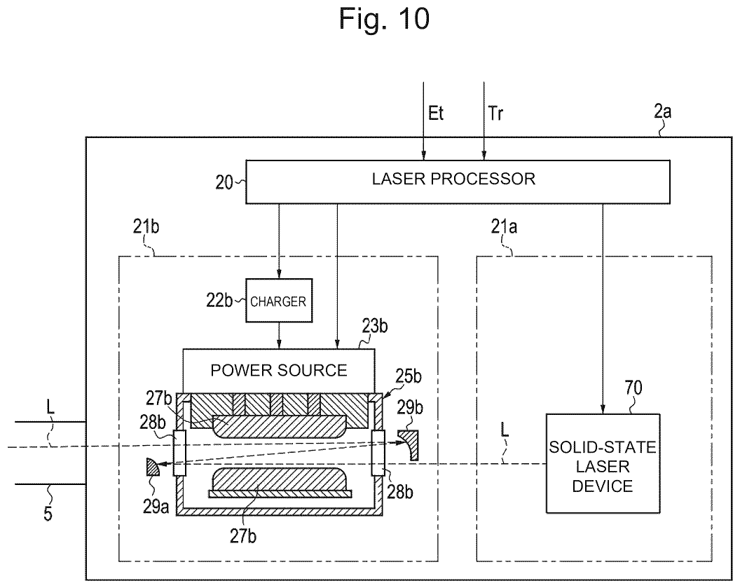

FIG. 10 schematically illustrates a configuration of a laser apparatus 2a according to a modification. The laser apparatus 2a differs from the configuration of the laser apparatus 2 in that a solid-state laser device 70 is used as the master oscillator 21a and that the excimer amplifier 21b is a power amplifier.

The solid-state laser device 70 outputs the laser beam L having a wavelength of about 193.4 nm as seed light. The laser beam L output from the solid-state laser device 70 is linearly polarized. The solid-state laser device 70 is disposed such that the laser beam L enters a discharge space of the excimer amplifier 21b.

In the excimer amplifier 21b according to the present modification, a convex cylindrical mirror 29a is provided instead of the output coupling mirror 26b, and a concave cylindrical mirror 29b is provided instead of the rear mirror 24b. Other components are similar to those of the excimer amplifier 21b illustrated in FIG. 2.

The convex cylindrical mirror 29a and the concave cylindrical mirror 29b are disposed such that the laser beam L output from the solid-state laser device 70 is reflected by the convex cylindrical mirror 29a and the concave cylindrical mirror 29b and passes through the discharge space three times. By passing through the discharge space three times, the laser beam L is amplified and beam-expanded in a discharge direction, and is then output.

Surfaces of the convex cylindrical mirror 29a and the concave cylindrical mirror 29b may be coated with a high reflective coating that highly reflects the deep ultraviolet light having the wavelength of about 193.4 nm.

The laser processor 20 controls switches of a power source of the solid-state laser device 70 and the power source 23b so that the excimer amplifier 21b discharges to amplify the laser beam L at a timing when the laser beam L output from the master oscillator 21a passes through the excimer amplifier 21b. Other control by the laser processor 20 is the same as that of the first embodiment.

As another modification of the laser apparatus 2, the laser apparatus 2a may be formed of one solid-state laser device 70. In this case, the solid-state laser device 70 may be disposed such that the laser beam output from the solid-state laser device 70 directly enters the optical device 41 without providing the excimer amplifier 21b.

### 6. Electronic Device Manufacturing Method

A laser processing method according to the embodiments can be applied to formation of through-holes in a glass substrate included in an interposer 102 in manufacturing of an electronic device 100 described below.

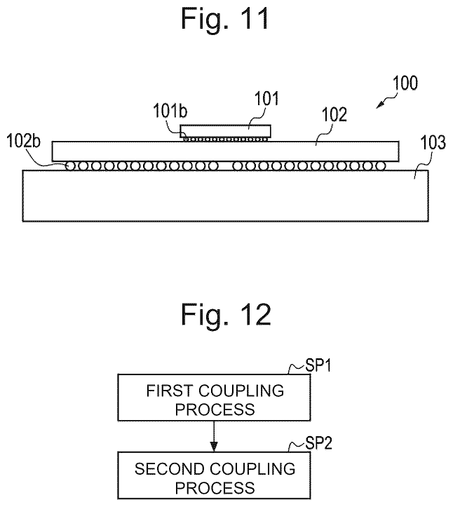

FIG. 11 schematically illustrates a configuration of the electronic device 100. The electronic device 100 illustrated in FIG. 11 includes an integrated circuit chip 101, the interposer 102, and a circuit board 103. The integrated circuit chip 101 is, for example, a chip-shaped integrated circuit board in which an integrated circuit is formed on a silicon substrate. The integrated circuit chip 101 is provided with a plurality of bumps 101b to be electrically connected to the integrated circuit.

The interposer 102 includes an insulating glass substrate in which a plurality of through-holes are formed, and a conductor that electrically connects front and back of the glass substrate is provided in each of the through-holes. A plurality of lands to be connected to the bumps 101b provided on the integrated circuit chip 101 are formed on one surface of the interposer 102, and each land is electrically connected to any one of the conductors in the through-holes. A plurality of bumps 102b are provided on the other surface of the interposer 102, and each bump 102b is electrically connected to any one of the conductors in the through-holes.

A plurality of lands to be connected to the respective bumps 102b are formed on one surface of the circuit board 103. The circuit board 103 includes a plurality of terminals electrically connected to the lands.

FIG. 12 illustrates a method of manufacturing the electronic device 100. As illustrated in FIG. 12, the method of manufacturing the electronic device 100 in the present description includes a first coupling step SP1 and a second coupling step SP2. In the first coupling step SP1, the integrated circuit chip 101 and the interposer 102 are coupled to each other.

Specifically, the bumps 101b of the integrated circuit chip 101 are disposed on the respective lands of the interposer 102 to electrically connect the bumps 101b and the lands. Thus, the integrated circuit chip 101 and the interposer 102 are electrically connected.

In the second coupling step SP2, the interposer 102 and the circuit board 103 are coupled to each other. Specifically, the bumps 102b of the interposer 102 are disposed on the respective lands of the circuit board 103 to electrically connect the bumps 102b and the lands. Thus, the integrated circuit chip 101 is electrically connected to the circuit board 103 via the interposer 102. Through these steps, the electronic device 100 is manufactured.

### 7. Configuration Example of Laser Processing Processor

In the present disclosure, the laser processing processor 40 is composed of, for example, a central processing unit (CPU). The laser processing processor 40 executes the various kinds of processing described above based on a program stored in a memory. Part or all of functions of the laser processing processor 40 may be realized using an integrated circuit, typically a field programmable gate array (FPGA) or an application specific integrated circuit (ASIC).

Note that the laser processing processor 40 may include functions of the laser processor 20. That is, the laser processing processor 40 and the laser processor 20 may be composed of one processor.

The description above is intended to be illustrative and the present disclosure is not limited thereto. Therefore, it would be obvious to those skilled in the art that various modifications to the embodiments of the present disclosure would be possible without departing from the spirit and the scope of the appended claims.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A laser processing system comprising:
a laser apparatus configured to output a deep ultraviolet laser beam in response to reception of a light emission trigger signal;
an optical isolator including a polarizer and a deep ultraviolet light transmitting element disposed on an optical path of the laser beam, and a piezoelectric element connected to the deep ultraviolet light transmitting element; and
a processor configured to supply, to the piezoelectric element, a drive signal having a voltage changeable with a natural frequency of the deep ultraviolet light transmitting element, and to transmit the light emission trigger signal to the laser apparatus using the natural frequency or a frequency obtained by dividing the natural frequency as a repetition frequency so that the deep ultraviolet light transmitting element functions as a ¼ wave plate by stress birefringence generated in response to force applied from the piezoelectric element at a timing when the laser beam passes through the deep ultraviolet light transmitting element,
the laser processing system performing processing by irradiating a workpiece with the laser beam output from the optical isolator.

2. The laser processing system according to claim 1, wherein
the laser apparatus includes
a master oscillator configured to output the laser beam, and
an excimer amplifier configured to amplify the laser beam output from the master oscillator.

3. The laser processing system according to claim 2, wherein
the master oscillator is an excimer laser apparatus.

4. The laser processing system according to claim 2, wherein
the master oscillator is a solid-state laser device.

5. The laser processing system according to claim 2, wherein
the excimer amplifier includes an optical resonator.

6. The laser processing system according to claim 1, further comprising
a light condensing optical system configured to condense the laser beam output from the optical isolator onto the workpiece.

7. The laser processing system according to claim 1, further comprising:
a photomask;
an illumination optical system disposed on an optical path of the laser beam and configured to illuminate the photomask with the laser beam; and
a projection optical system configured to project the laser beam that has passed through the photomask onto the workpiece, wherein
the optical isolator is disposed on an optical path of the laser beam between the photomask and the projection optical system.

8. The laser processing system according to claim 1, wherein
the deep ultraviolet light transmitting element is formed of calcium fluoride or synthetic quartz.

9. The laser processing system according to claim 1, wherein
the polarizer is an optical element configured to transmit one of two linearly polarized light beams having orthogonal polarization directions and to reflect the other, and
the deep ultraviolet light transmitting element is disposed on an optical path of the laser beam transmitted through the polarizer.

10. A laser processing method for performing processing through irradiation to a workpiece by a laser processing system including
a laser apparatus configured to output a deep ultraviolet laser beam in response to reception of a light emission trigger signal and
an optical isolator including a polarizer and a deep ultraviolet light transmitting element disposed on an optical path of the laser beam, and a piezoelectric element connected to the deep ultraviolet light transmitting element, the method comprising:
supplying, to the piezoelectric element, a drive signal having a voltage changeable with a natural frequency of the deep ultraviolet light transmitting element;
transmitting the light emission trigger signal to the laser apparatus using the natural frequency or a frequency obtained by dividing the natural frequency as a repetition frequency so that the deep ultraviolet light transmitting element functions as a ¼ wave plate by stress birefringence generated in response to force applied from the piezoelectric element at a timing when the laser beam passes through the deep ultraviolet light transmitting element; and
performing processing by irradiating the workpiece with the laser beam output from the optical isolator.

11. An electronic device manufacturing method comprising:
forming, by a laser processing system, a plurality of through-holes in a glass substrate as a workpiece, the laser processing system including
a laser apparatus configured to output a deep ultraviolet laser beam in response to reception of a light emission trigger signal,
an optical isolator including a polarizer and a deep ultraviolet light transmitting element disposed on an optical path of the laser beam, and a piezoelectric element connected to the deep ultraviolet light transmitting element, and
a processor configured to supply, to the piezoelectric element, a drive signal having a voltage changeable with a natural frequency of the deep ultraviolet light transmitting element, and to transmit the light emission trigger signal to the laser apparatus using the natural frequency or a frequency obtained by dividing the natural frequency as a repetition frequency so that the deep ultraviolet light transmitting element functions as a ¼ wave plate by stress birefringence generated in response to force applied from the piezoelectric element at a timing when the laser beam passes through the deep ultraviolet light transmitting element,
the laser processing system performing processing by irradiating the workpiece with the laser beam output from the optical isolator;
coupling and electrically connecting an interposer and an integrated circuit chip to each other, the interposer including the glass substrate and conductors provided in the respective through-holes; and
coupling and electrically connecting the interposer and a circuit board to each other.
